(19) United States
(12) Patent Application Publication
(10) Pub. No.: US 2010/0291491 A1
(43) Pub. Date: Nov. 18, 2010

(54) Resist pattern slimming treatment method

(75) Inventors: Masahiro Yamamoto, Koshi City (JP); Yoshihiro Kondo, Koshi City (JP); Atsushi Ookouchi, Koshi City (JP); Toyohisa Tsuruda, Koshi City (JP)

Correspondence Address: POSZ LAW GROUP, PLC, 12040 SOUTH LAKES DRIVE, SUITE 101, RESTON, VA, 20191, US

(73) Assignee: Tokyo Electron Limited, Tokyo (JP)

(21) Appl. No.: 12/662,343

(22) Filed: Apr. 13, 2010

(30) Foreign Application Priority Data
May 15, 2009 (JP) 2009-119087

(51) Int. Cl. G03F 7/38

(52) U.S. Cl. 430/423

(57) ABSTRACT

A resist pattern slimming treatment method of performing a slimming treatment on a resist pattern formed on a substrate includes: a slimming treatment step of performing a slimming treatment on the resist pattern by applying a reactant solubilizing the resist pattern onto the resist pattern, then performing a heat treatment on the resist pattern under a heat treatment condition determined in advance, and then performing a developing treatment on the resist pattern; and a first line width measurement step of measuring a line width of the resist pattern before the slimming treatment step. The heat treatment condition is determined based on a measurement value of the line width measured in the first line width measurement step.

### BACKGROUND OF THE INVENTION

1. Field of the Invention

The present invention relates to a resist pattern slimming treatment method of performing a slimming treatment on a resist pattern formed on a substrate, in a semiconductor process or the like.

2. Description of the Related Art

With increased miniaturization of semiconductor devices, it has become more difficult to secure a sufficient exposure contrast of a fine pattern having a ratio between the line width and the space width being 1:1 only by using optical exposure technology. Hence, a technique of forming a fine pattern by combining a new layer to a pattern or a technique of forming a fine pattern by performing the pattern formation in two steps has been discussed. However, it is important in any of the techniques how to form a reduced line width of the pattern. Examples of a slimming treatment method that is a method of the treatment in which a series of photolithography composed of resist coating, heat treatment, exposure processing and developing treatment is performed to form a resist pattern on a substrate, and then the line width of the formed resist pattern is reduced (hereinafter, referred to as a “slimming treatment”), include the following ones.

There is a method in which a resist pattern is formed using a chemically amplified resist, and then an acid coating is applied on the resist pattern so that a surface layer of the resist pattern changes to be alkali-soluble, and the surface layer changed to be alkali-soluble is removed, whereby the line width of the resist pattern is made smaller than the line width that has been formed first (see, for example, Japanese Patent Application Laid-open No. 2001-281886).

There is another method in which a resist pattern is formed using a chemically amplified resist, then a modifying material is applied onto the resist pattern and diffused into the resist pattern, and thereafter the modifying material and a portion of the resist pattern which has been made soluble by diffusion of the modifying material are removed, whereby the line width of the resist pattern is made smaller than the line width that has been formed first (see, for example, Japanese Patent Application Laid-open No. 2002-299202).

There is still another method in which a resist pattern is formed, then a pattern thinning material (shrinking material) is applied onto the resist pattern to form a pattern mixing layer on the front surface of the resist pattern, and thereafter the thinning material and the pattern mixing layer are removed, whereby the line width of the resist pattern is made smaller than the line width that has been formed first (see, for example, Japanese Patent Application Laid-open No. 2003-215814).

### SUMMARY OF THE INVENTION

However, when reducing the line width of the resist pattern using the above-described slimming treatment method, there is a following problem.

The problem is that when there are variations in line width or shape in a process before the slimming treatment process of performing the slimming treatment, the process subsequent thereto needs to be performed with the variations in line width or shape remaining, in the slimming treatment process.

Before the slimming treatment process is performed, an exposure and development process of performing exposure processing and developing treatment to form a resist pattern is performed. However, because the line width of a mask pattern when performing the exposure processing is also reduced for miniaturization of the pattern of the semiconductor device, variations may occur in the finished line width of the resist pattern formed by performing the exposure and development process, due to little variations in resist film thickness among substrates and little variations in resist film thickness within a substrate.

On the other hand, in the slimming treatment process, a slimming condition is set to reduce the line width by a fixed amount. Therefore, when the slimming treatment is performed on resist patterns formed on substrates which have variations in line width among the substrates, variations in line width reflecting the variations in line width before the slimming treatment may exist also in the resist patterns which have been subjected to the slimming treatment.

The present invention has been made in consideration of the above points, and an object thereof is to provide a resist pattern slimming treatment method capable of, when performing a slimming treatment on a resist pattern formed by performing exposure processing and developing treatment, determining a treatment condition of the slimming treatment to correct variations in line width of the formed resist pattern and reducing the variations in line width of the resist pattern after the slimming treatment.

To solve the above problem, the present invention is characterized by devising the means described below.

The resist pattern slimming treatment method according to the present invention is a resist pattern slimming treatment method of performing a slimming treatment on a resist pattern formed on a substrate, including: a slimming treatment step of performing a slimming treatment on the resist pattern by applying a reactant solubilizing the resist pattern onto the resist pattern, then performing a heat treatment on the resist pattern under a heat treatment condition determined in advance, and then performing a developing treatment on the resist pattern; and a first line width measurement step of measuring a line width of the resist pattern before the slimming treatment step, wherein the heat treatment condition is determined based on a measurement value of the line width measured in the first line width measurement step.

According to the present invention, when performing the slimming treatment on the resist pattern formed by performing exposure processing and developing treatment, the treatment condition of the slimming treatment can be determined to correct the variations in line width of the formed resist pattern so as to reduce the variations in line width of the resist pattern after the slimming treatment.

### BRIEF DESCRIPTION OF THE DRAWINGS

FIG. 1 is a plan view showing the overall configuration of a coating and developing apparatus according to a first embodiment of the present invention;

FIG. 2 is a perspective view showing the overall configuration of the coating and developing apparatus according to the first embodiment of the present invention;

FIG. 3 is a longitudinal side view of the coating and developing apparatus according to the first embodiment of the present invention;

FIG. 4 is a configuration diagram of a control unit of the coating and developing apparatus according to the first embodiment of the present invention;

FIG. 5 is a flowchart for explaining a procedure of processes of a resist pattern slimming treatment method and a resist pattern forming method according to the first embodiment of the present invention;

FIG. 6A is a sectional view schematically showing the structure on a front surface of a substrate at one step of the resist pattern slimming treatment method according to the first embodiment of the present invention;

FIG. 6B is a sectional view schematically showing the structure on the front surface of the substrate at one step of the resist pattern slimming treatment method according to the first embodiment of the present invention;

FIG. 6C is a sectional view schematically showing the structure on the front surface of the substrate at one step of the resist pattern slimming treatment method according to the first embodiment of the present invention;

FIG. 6D is a sectional view schematically showing the structure on the front surface of the substrate at one step of the resist pattern slimming treatment method according to the first embodiment of the present invention;

FIG. 6E is a sectional view schematically showing the structure on the front surface of the substrate at one step of the resist pattern slimming treatment method according to the first embodiment of the present invention;

FIG. 6F is a sectional view schematically showing the structure on the front surface of the substrate at one step of the resist pattern slimming treatment method according to the first embodiment of the present invention;

FIG. 6G is a sectional view schematically showing the structure on the front surface of the substrate at one step of the resist pattern slimming treatment method according to the first embodiment of the present invention;

FIG. 7 is a graph showing the relation between the heat treatment temperature in a heat treatment process and the slimming width which is held in advance in the control unit before the resist pattern slimming treatment method according to first embodiment of the present invention is started;

FIG. 8 is a flowchart for explaining a procedure of processes of the conventional resist pattern slimming treatment method and resist pattern forming method;

FIG. 9 is a graph for explaining that variations in line width before the slimming treatment process are not corrected in the conventional resist pattern slimming treatment method;

FIG. 10 is a sectional view schematically showing the structure on the front surface of the substrate at Step S17 and Step S18 when the resist pattern slimming treatment method according to a modification example of the first embodiment of the present invention has been performed;

FIG. 11 is a flowchart for explaining a procedure of processes of a resist pattern slimming treatment method and a resist pattern forming method according to a second embodiment of the present invention; and

FIG. 12 is a graph showing the operation and effect capable of correcting the variations in line width before the slimming treatment process to reduce the variations in line width after the slimming treatment process in the resist pattern slimming treatment method according to the second embodiment of the present invention.

### DETAILED DESCRIPTION OF THE INVENTION

Embodiments for implementing the present invention will be described below with reference to the drawings.

### First Embodiment

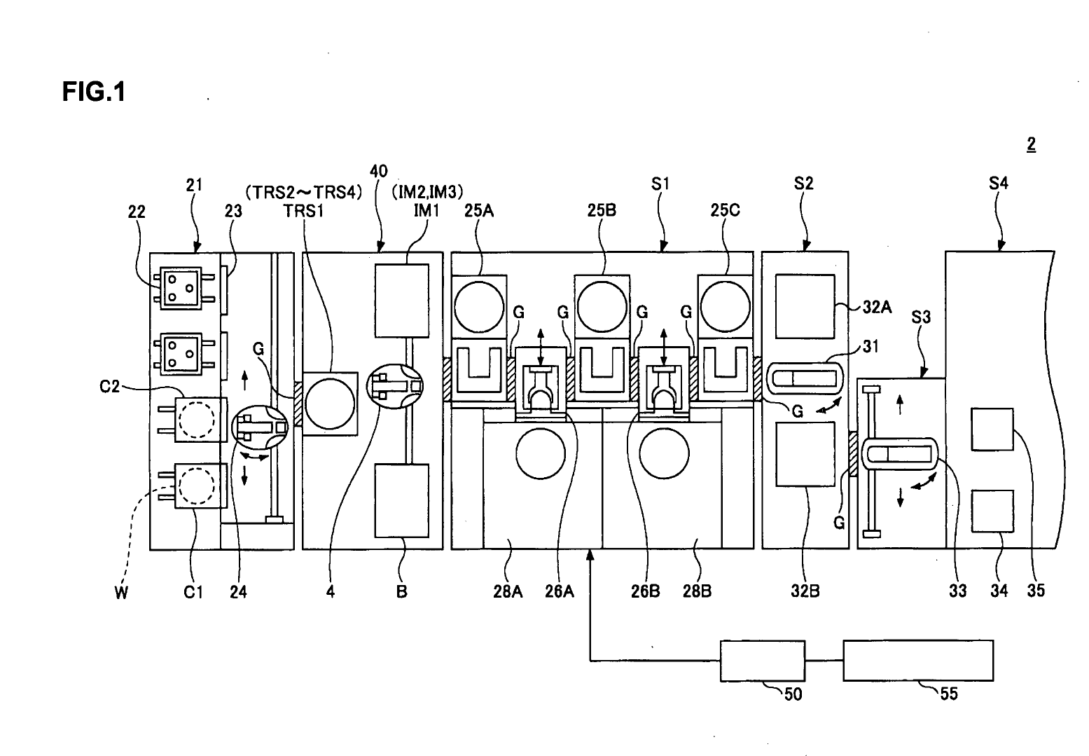

At the beginning, a resist pattern slimming treatment method and a coating and developing apparatus used for performing the slimming treatment method, which are a first embodiment of the present invention will be described with reference to FIG. 1 to FIG. 7.

First, the coating and developing apparatus according to this embodiment will be described with reference to FIG. 1 to FIG. 4.

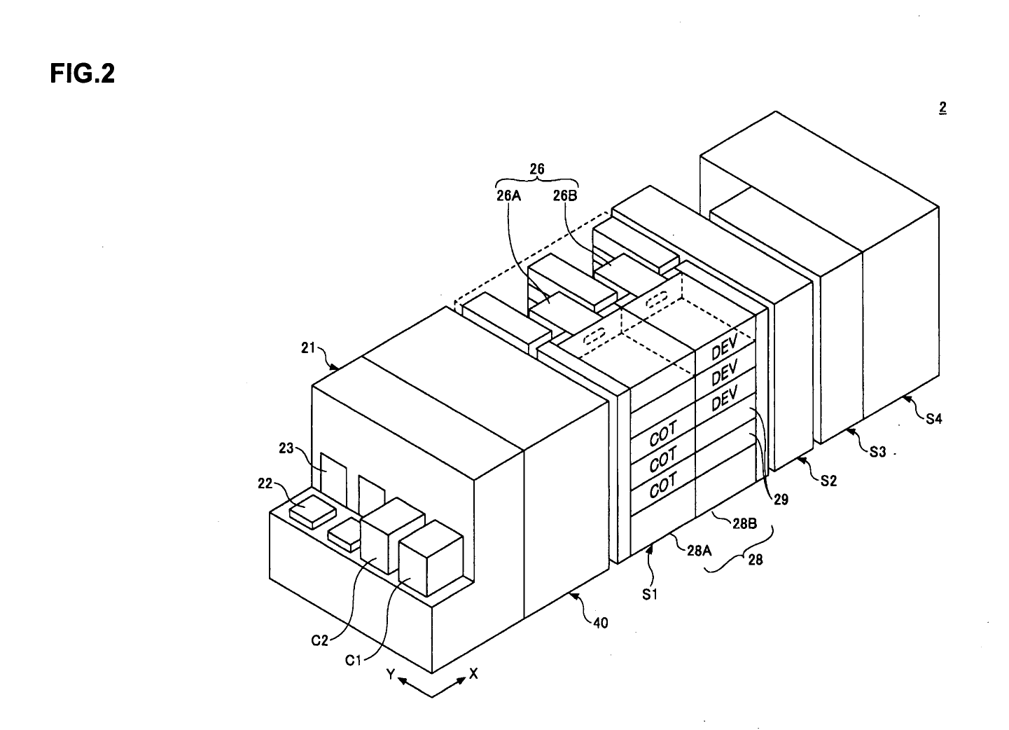

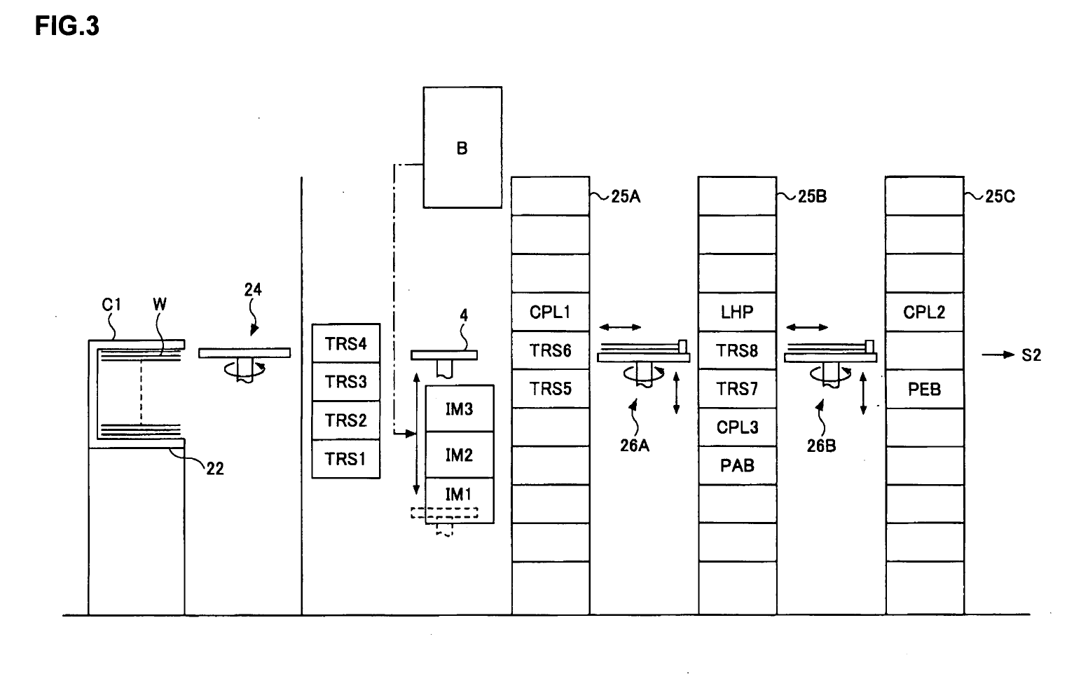

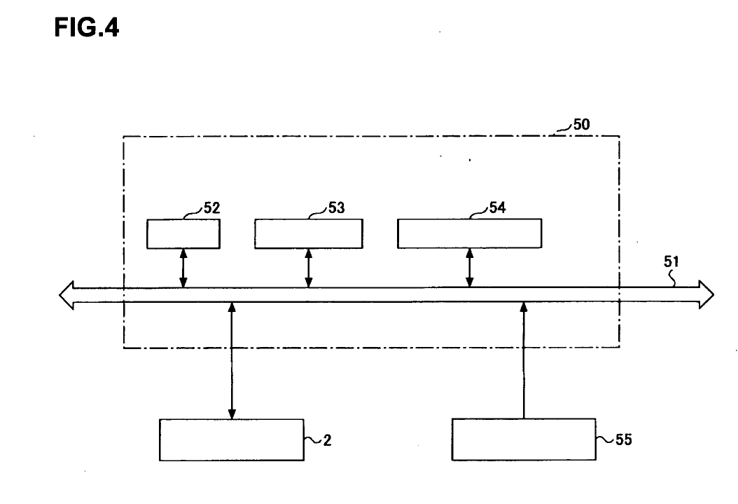

FIG. 1 is a plan view showing the overall configuration of the coating and developing apparatus according to this embodiment. FIG. 2 is a perspective view showing the overall configuration of the coating and developing apparatus according to this embodiment. FIG. 3 is a longitudinal side view of the coating and developing apparatus according to this embodiment. FIG. 4 is a configuration diagram of a control unit of the coating and developing apparatus according to this embodiment.

As shown in FIG. 1 and FIG. 2, a coating and developing apparatus 2 has a carrier block 21, an inspection block 40, a treatment block S1, a first interface block S2, a second interface block S3, and an aligner S4, in order from the front side (the negative direction side in an X-direction in FIG. 2). In the carrier block 21, a plurality of carriers C1 and C2 housing wafers W are mounted. To the back side of the carrier block 21 (the positive direction side in the X-direction in FIG. 2), the inspection block 40 and the treatment block S1 that are surrounded by respective casings are connected in this order. To the back side of the treatment block S1, the aligner S4 is connected via the first interface block S2 and the second interface block S3.

In the carrier block 21, a mounting section 22 for mounting the plurality of carriers C1 and C2 thereon, opening/closing units 23 provided in a forward wall surface as viewed from the mounting section 22, and a delivery arm 24 that is a delivery means for taking wafers W out of the carriers C1 and C2 via the opening/closing units 23, are provided. The delivery arm 24 is configured to freely lift up and down, move right and left and back and forth, and rotate around the vertical axis. The delivery arm 24 is controlled based on a command from a later-described control unit 50.

In each of the carriers C1 and C2, for example, 25 wafers W being substrates that will be subjected to coating and developing treatments are housed. The carrier C1 housing the wafers W that will be subjected to the coating and developing treatments and the carrier C2 housing the wafers W that will not be subjected to the coating and developing treatments but only to inspection are transferred in/out by a not-shown transfer mechanism from/to the outside of the coating and developing apparatus 2.

As shown in FIG. 3, the inspection block 40 includes: four delivery stages TRS1 to TRS4; inspection modules IM1 to IM3; a transfer arm 4 being a substrate transfer means delivering the wafer W between the delivery stages TRS1 to TRS4, the inspection modules IM1 to IM3, and delivery stages TRS5 and TRS6 in the treatment block S1; and a buffer module B temporarily storing the wafer W transferred from the treatment block S1 into the inspection block 40. The delivery stages TRS1 to TRS4 that are first to fourth stages are vertically stacked as shown in FIG. 3. Further, the inspection modules IM1 to IM3 are also vertically stacked.

The inspection module IM1 is a film thickness and line width inspection module measuring the thickness of a film formed on the wafer W and the line width of a pattern. As the film thickness and line width inspection module, for example, an optical digital profilometry (ODP) system including scatterometry can be used.

Besides, as the inspection module IM2, a macro inspection module detecting macro defects on the wafer W can be provided. Alternatively, as the inspection module IM3, an overlay inspection module detecting overlay misalignment of exposure, that is, the displacement between the formed pattern and an underlying pattern can be provided.

As shown in FIG. 1 and FIG. 3, in the treatment block S1, three shelf modules 25A, 25B, and 25C in each of which modules of a heating and cooling system are multi-tiered, and two main arms 26A and 26B that are main transfer means for delivering the wafer W between later-described solution treatment modules, are provided such that they are alternately arranged in order from the front side. Each of the main arms 26A and 26B includes two arms which are configured to freely lift up and down, move right and left and back and forth, and rotate around the vertical axis. Each of the main arms 26A and 26B is controlled based on a command from the later-described control unit 50.

The shelf modules 25A, 25B, and 25C and the main arms 26A and 26B are arranged one behind the other in a line as view from the side of the carrier block 21, and a not-shown opening portion for wafer transfer is formed in each connection region G. Therefore, the wafer W can be freely moved in the treatment block S1 from the shelf module 25A on one end side to the shelf module 25C on the other end side. Further, each of the main arms 26A and 26B is placed in a space surrounded by a partition wall composed of face portions on the side of the shelf modules 25B and 25A or 25C which are arranged in a forward and backward direction as viewed from the carrier block 21, one face portion on the side of, for example, the solution treatment unit on the right side, and a rear face portion forming one face of the treatment block S1 on the left side.

As shown in FIG. 2, at positions where the wafers W are delivered by the main arms 26A and 26B, solution treatment modules 28A and 28B in each of which solution treatment units such as coating modules COT applying a resist and developing units DEV are multi-tiered are provided. Each of the solution treatment modules 28A and 28B is configured such that treatment containers 29 housing the solution treatment units therein are stacked at a plurality of, for example, five tiers.

Further, in the shelf modules 25A, 25B, and 25C, delivery stages TRS5 to TRS8 for delivering the wafer W, a heating module LHP forming heating units for performing a heating treatment on the wafer W after application of a developing solution, cooling modules CPL1, CPL2, and CPL3 forming cooling units for performing a cooling treatment on the wafer W before and after application of the resist solution and before the developing treatment, a heating module PAB being a heating unit performing a heating treatment on the wafer W before exposure processing and a heating module PEB forming a heating unit performing a heating treatment on the wafer W after exposure processing and so on are assigned, for example, to ten tiers in the vertical direction as shown in FIG. 3. Here, the delivery stages TRS5 and TRS6 are used for delivering the wafer W between the inspection block 40 and the treatment block S1, and the delivery stages TRS 7 and TRS8 are used for delivering the wafer W between the two main arms 26A and 26B. In this example, the heating module LHP, the heating module PAB, the heating module PEB, and the cooling modules CPL1, CPL2, and CPL3 correspond to the treatment modules.

As shown in FIG. 1, the first interface block S2 includes: a delivery arm 31 which is configured to freely lift up and down and rotate around the vertical axis and delivers the wafer W to/from the cooling module CPL2 and the heating module PEB in the shelf module 25C of the treatment block S1 as described later; a shelf module 32A in which an in-buffer cassette for temporarily housing the wafer W to be transferred into an edge exposure unit and the aligner S4 and an out-buffer cassette for temporarily housing the wafer W transferred out of the aligner S4 are multi-tiered; and a shelf module 32B in which a delivery stage for the wafer W and a high-precision temperature regulating module are multi-tiered.

The second interface block S3 includes a delivery arm 33. The delivery arm 33 delivers the wafer W to/from the delivery stage and the high-precision temperature regulating module in the first interface block S2, and an in-stage 34 and an out-stage 35 in the aligner S4.

Next, the flow of a wafer when coating and developing treatments are performed on the wafer in the treatment block S1 will be described.

When the carrier C1 housing wafers W which will be subjected to coating and developing treatments is transferred into the carrier block 21 from the outside, the opening/closing unit 23 is opened and a lid body of the carrier C1 is removed, and the wafer W is taken out by the delivery arm 24. The wafer W is delivered from the delivery arm 24 to the delivery stage TRS1 and transferred by the transfer arm 4 in the inspection module 40 to the delivery arm TRS5. Subsequently, the main arm 26A receives the wafer W from the delivery stage TRS5. Thereafter, the wafer W is transferred by the main arms 26A and 26B through the route of the delivery stage TRS5, the cooling module CPL1, the coating module COT, the delivery state TRS7, the heating module PAB, and the cooling module CPL2. The wafer W on which the resist solution has been applied in this manner is transferred to the first interface block S2 via the cooling module CPL2.

In the first interface block S2, the wafer W is transferred by the delivery arm 31 in the order of the in-buffer cassette, the edge exposure unit, and the high-precision temperature regulating module, and transferred via the delivery stage in the shelf module 32B to the second interface block S3. Thereafter, the wafer W is transferred by the delivery arm 33 via the in-stage 34 in the aligner S4 to the aligner S4, where the wafer W is subjected to exposure.

After the exposure, the wafer W is transferred in the order of the out-stage 35, the second interface block S3, and the out-buffer cassette in the first interface block S2, and then transferred via the delivery arm 31 to the heating module PEB in the treatment block S1. Thereafter, the wafer W is transferred through the route of the cooling module CPL3, the developing unit DEV, the heating module LHP, the delivery state TRS8, and the delivery stage TRS6. In this manner, a predetermined resist pattern is formed on the wafer W on which a predetermined developing treatment has been performed in the developing unit DEV.

The coating and developing apparatus 2 is provided with the control unit 50 including, for example a computer, and its configuration is shown in FIG. 4. In FIG. 4, numeral 51 denotes a bus, and a CPU 52 and a work memory 53 for performing various kinds of calculation are connected to the bus 51. A program storage unit 54 in which various kinds of programs are stored is also connected to the bus 51. The programs are stored in the program storage unit 54 while being stored in a storage medium such as a hard disk, a compact disk, a magneto-optical disk, or a memory card.

To the control unit 50, a host computer 55 is connected. The host computer 55 identifies, for each carrier transferred to the coating and developing apparatus 2, the lot of wafers housed in the carrier for which what kind of treatment will be performed, for example, by an identification code. The host computer 55 transmits a signal corresponding to the identification code to the control unit 50 by the time when the carrier C1, C2 is transferred to the coating and developing apparatus 2. The control unit 50 reads various kinds of programs based on the signal, and a series of treatment processes including the transfer operation of the delivery arm 24 and the transfer arm 4 are controlled by the read programs.

Further, the control unit 50 is configured to assign wafer numbers to 25 wafers W housed in each of the carriers C1 and C2 in the order of the wafers W transferred into the carrier block 21. An operator can set whether to perform inspection in one or more of the inspection modules IM1 to IM3 or not at all, for the first wafer “1” to the last wafer “25” in each lot, from an input screen before the carrier C1, C2 is transferred into the coating and developing apparatus 2.

For the lot for which a normal slimming treatment is performed, the control unit 50 further obtains, holds, and manages data obtained by line width measurement of a resist pattern formed by performing coating and developing treatments, for each carrier transferred to the coating and developing apparatus 2. Further, prior to performance of treatment on the lot for which the normal slimming treatment will be performed, for example, the slimming treatment process is performed on a plurality of wafers with a treatment condition such as a heat treatment condition or the like changed, and the control unit 50 obtains data of the slim amount that is the difference between line widths before and after performance of the slimming treatment process for each of the wafers and holds data of the correlation between the treatment condition of the slimming treatment the slim amount.

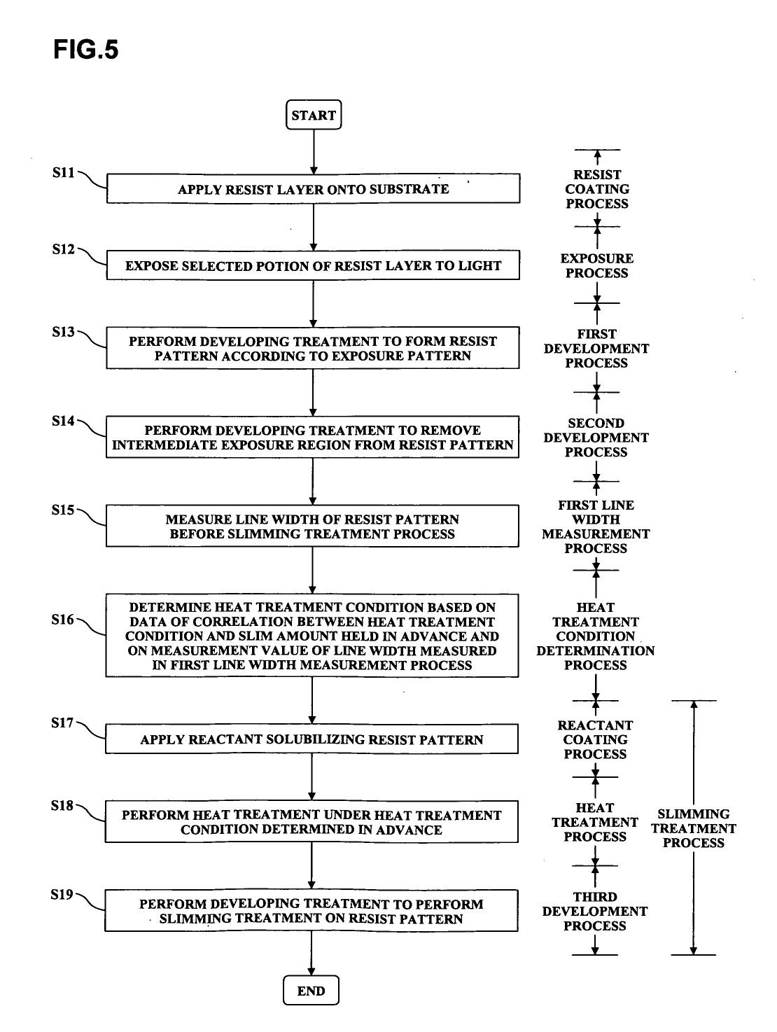

Next, the slimming treatment method and a resist pattern forming method according to this embodiment will be described with reference to FIG. 5 to FIG. 7.

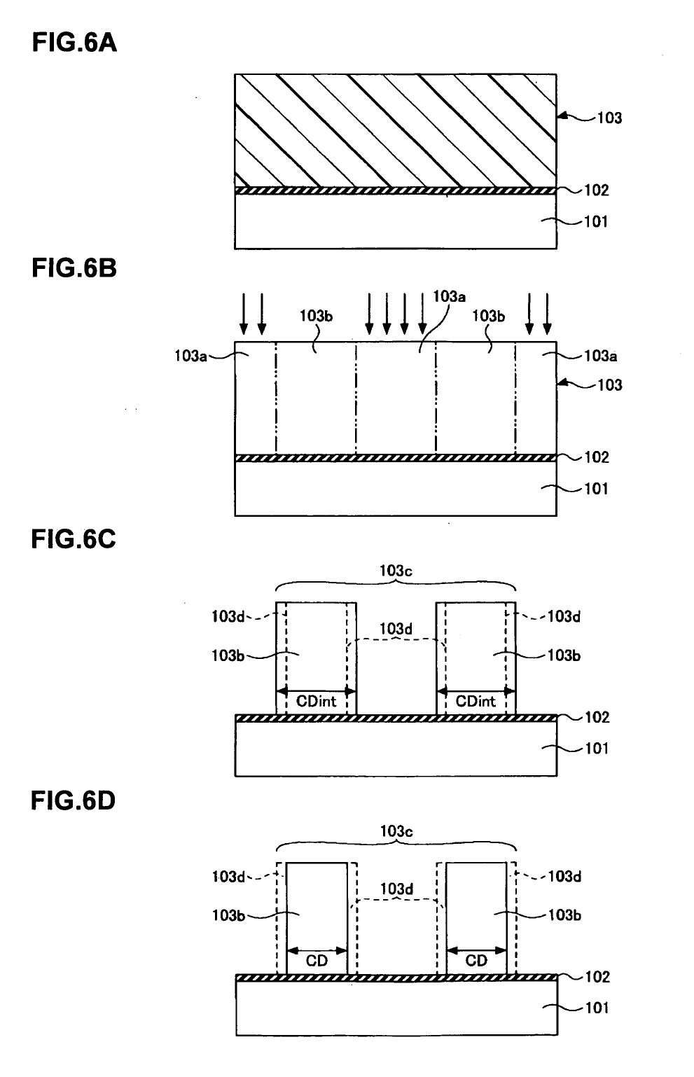

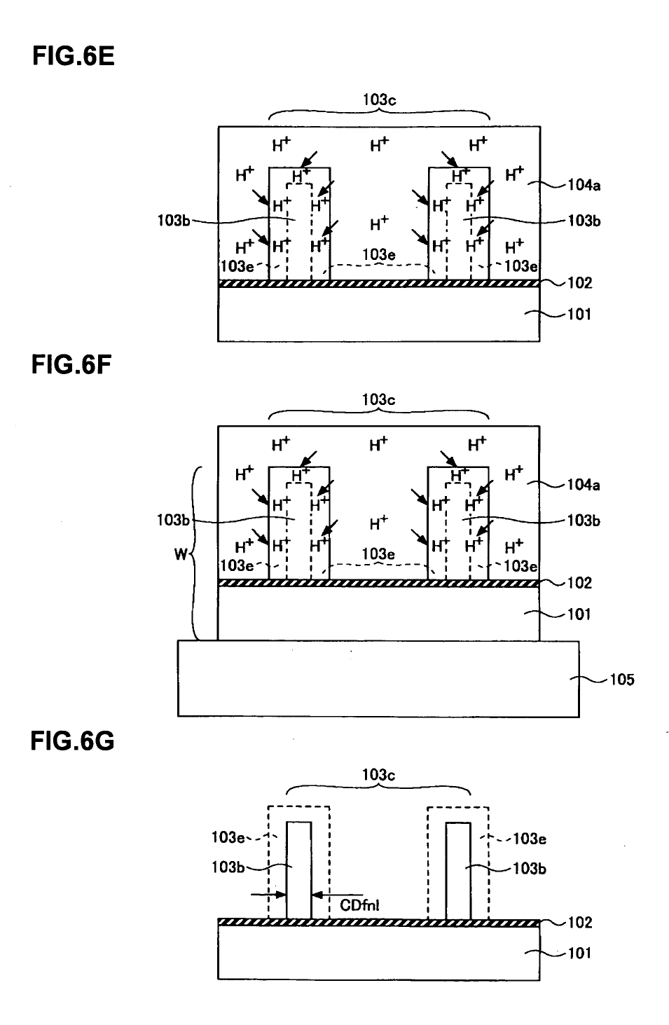

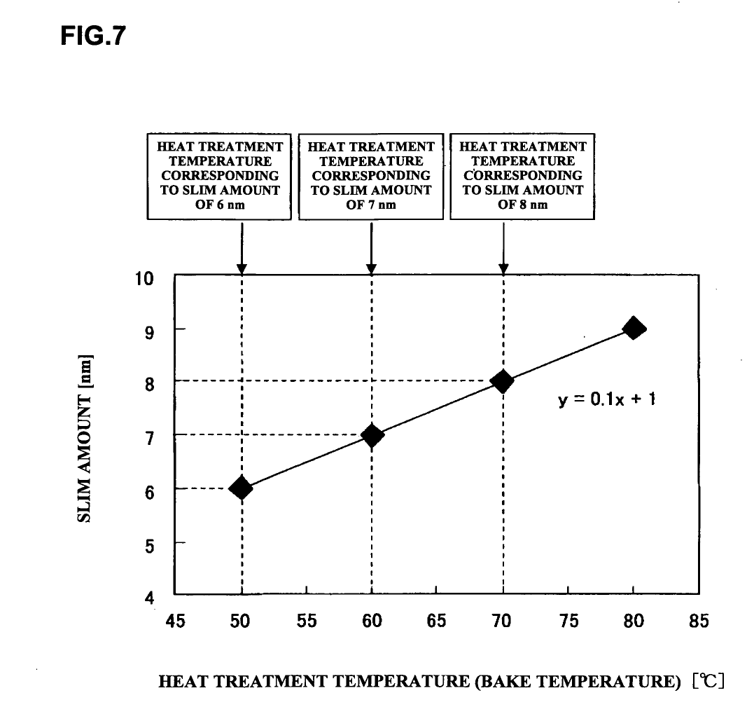

FIG. 5 is a flowchart for explaining a procedure of processes of the resist pattern slimming treatment method and the resist pattern forming method according to this embodiment. FIG. 6A to FIG. 6G are sectional views each schematically showing the structure on the front surface of a substrate in each of the steps in the resist pattern slimming treatment method according to this embodiment. FIG. 7 is a graph showing the relation between the heat treatment temperature in the heat treatment process and the slimming width which is held in advance in the control unit 50 before the resist pattern slimming treatment method according to this embodiment is started.

Note that FIG. 6A to FIG. 6G each show the structure on the front surface of the substrate after Step S11 to Step S14 and Step S17 to Step S19 are performed.

The resist pattern forming method including the resist pattern slimming treatment method according to this embodiment includes, as shown in FIG. 5, a resist coating process (Step S11), an exposure process (Step S12), a first development process (Step S13), a second development process (Step S14), a first line width measurement process (Step S15), a heat treatment condition determination process (Step S16), and a slimming treatment process (Step S17 to Step S19). Further, the slimming treatment process includes a reactant coating process (Step S17), a heat treatment process (Step S18), and a third development process (Step S19). Further, the resist pattern slimming treatment method according to this embodiment includes the first line width measurement process at Step S15 to the third development process at Step S19.

First of all, the resist coating process at Step S11 is performed. The resist coating process is a process of applying a bottom anti-reflection coating (BARC) 102 and a resist layer 103 on a base layer 101. FIG. 6A shows the structure of a resist pattern after the process at Step S11 is performed.

At Step S11, the bottom anti-reflection coating 102 is first formed on the base layer 101. An example of the base layer 101 is a semiconductor wafer itself, and a semiconductor device internal structure such as an inter-layer insulating film formed on the semiconductor wafer. The bottom anti-reflection coating 102 is formed, for example, by applying a resist to which an anti-reflection agent is added or depositing a bottom anti-reflection coating. Note that the bottom anti-reflection coating 102 may be formed when necessary.

Subsequently, at Step S11, the coating module COT in the coating and developing apparatus 2 is used to apply a resist on the bottom anti-reflection coating 102, and pre-baking is performed on the applied resist to evaporate a solvent therein and harden the resist, thereby forming the resist layer 103 as shown in FIG. 6A. An example of the resist is a chemically amplified resist. An example of the chemically amplified resist is a resist which generates solubilized substance soluble in a solvent, for example, by being irradiated with light. As a concrete example, a chemically amplified resist which contains photoacid generator (PAG) and deals with exposure using an ArF excimer laser (having a wavelength of 193 nm) as a light source is used in this example. PAG generates acid when irradiated with light. Acid reacts with an alkali-insoluble protecting group contained in the resist and changes the alkali-insoluble protecting group into an alkali-soluble group (solubilized substance). An example of the above-described reaction is acid-catalyzed reaction.

Subsequently, the exposure process at Step S12 is performed. The exposure process is a process of exposing a selected portion of the resist layer 103 to light. FIG. 6B shows the structure of the resist pattern after the process at Step S12 is performed.

At Step S12, as shown in FIG. 6B, the selected portion of the resist layer 103 is exposed to light, whereby a solubilized substance which is soluble to an alkaline solvent (developing solution) is selectively generated. The resist in this example is the chemically amplified resist containing PAG. In this example, to activate the acid generated in the resist layer 103 and promote the change of the alkali-insoluble protecting group into the alkali-soluble group (solubilized substance), post-exposure bake (PEB) is performed. By selectively generating the solubilized substance as described above, an exposure pattern composed of, for example, a soluble layer 103a soluble in an alkaline solvent (developing solution) and an insoluble layer 103b insoluble in the alkaline solvent is obtained in the resist layer 103.

Subsequently, the first development process at Step S13 is performed. The first development process is a process of performing a developing treatment to form a resist pattern 103c according to the exposure pattern. FIG. 6C shows the structure of the resist pattern after the process at Step S13 is performed.

At Step S13, as shown in FIG. 6C, the developing unit DEV in the coating and developing apparatus 2 is used, for example, to remove the soluble layer 103a from the resist layer 103 in which the exposure pattern has been formed, to form a resist pattern 103c according to the exposure pattern. In this example, the soluble layer 103a is removed by spraying the alkaline solvent (developing solution) onto the resist layer 103 in which the exposure pattern has been formed. Thereby, the resist pattern 103c composed of the insoluble layer 103b is formed. Subsequently, post-bake is performed, when necessary, in order to harden the resist pattern 103c. Thus, the first development process ends. The line width of the resist pattern 103c after the first development process is performed is CDint.

Subsequently, the second development process at Step S14 is performed. The second development process is a process of removing an intermediate exposure region from the resist pattern 103c. FIG. 6D shows the structure of the resist pattern after the process at Step S14 is performed.

On a side surface of the resist layer 103 after the first development process is performed, there arises a region having an intermediate property between the soluble layer 103a and the insoluble layer 103b, namely, a region which is originally a soluble region but not completely solubilized or which is originally an insoluble region but has a small number of soluble groups generated therein. Such a region is called an intermediate exposure region 103d hereinafter. The reason why the intermediate exposure region 103d arises is, for example, that it is increasingly difficult, with increased miniaturization of the semiconductor device, to secure a sufficient contrast in exposure amount at the boundary between the exposed region and the not-exposed region.

At step S14, as shown in FIG. 6D, the intermediate region 103d is removed by performing a developing treatment, for example, with the temperature of the developing solution set at not lower than 23° C. nor higher than 50° C., the concentration of the developing solution set at not lower than 2.38% nor higher than 15%, and the developing time set at not shorter than 20 sec nor longer than 300 sec. By removing the intermediate region 103d, the resist pattern 103c having a line width CD smaller than the line width CDint of the resist pattern 103c after the first development process is performed can be formed.

Note that the second development process at Step S14 can be omitted. In other words, after the first development process at Step S13 is performed, the first line width measurement process at Step S15 may be performed with the second development process at Step S14 omitted.

Subsequently, the first line with measurement process being Step S15 is performed. The first line width measurement process is a process of measuring the line width of the resist pattern formed by performing the second development process (the first development process when the second development process is omitted).

The wafer is transferred, for example, to the inspection module IM1 being the film thickness and line width inspection module using the ODP including scatterometry, and the line width is measured.

In the ODP, as in spectroscopic ellipsometry or the like, polarized light is made incident on an object to be measured, and an amplitude ratio spectrum and a phase difference spectrum of reflection light being reflected incident light are measured, whereby the reflectance is measured. When the incident light composed of normal white light that is not polarized light passes through a polarizer, the incident light becomes a linearly polarized light having an electric field vector parallel to one axis of the polarizer. The linearly polarized light is composed of a p-polarized light having a vector component parallel to the incident plane that is a plane including the incident light and the reflection light, and an s-polarized light having a vector component perpendicular to the incident plane. The ellipsometry is a measurement method of measuring a change in polarized light generated when each of the p-polarized light and the s-polarized light of the incident light is reflected from a medium. The change in polarized light is composed of two components such as the change in amplitude (intensity) and the change in phase.

On the other hand, in the ODP, the reflectance when a cyclic pattern is formed on the substrate being an object to be measured is calculated. When the object to be measured is a cyclic pattern, the object to be measured can be regarded as a diffraction grating. The reflection light becomes a diffracted reflection light which is diffracted by the diffraction grating. As the calculation of the reflectance when the diffracted reflection light is reflected, for example, rigorous coupled wave analysis (hereinafter referred to as RCWA) can be used which is described in U.S. Pat. No. 5,835,225 or U.S. Pat. No. 5,739,909. On assumption of the material constant such as a dielectric constant and the like, the sectional shape of the diffraction grating is modeled by a method of approximating it as an aggregate of rectangular elements or the like, and the diffraction reflectance of the modeled sectional shape is calculated. The calculated value of the diffraction reflectance calculated as described above and the measurement value of the diffraction reflectance are compared and analyzed, whereby the sectional shape can be calculated. As a result, the line width of the resist pattern 103c can be measured.

Subsequently, the heat treatment condition determination process being Step S16 is performed. The heat treatment condition determination process is a process of determining a heat treatment condition based on the measurement value of the line width measured in the first line width measurement process.

Before start of the treatment on the wafer using the slimming treatment method according to this embodiment, the data of the correlation between the heat treatment condition and the slim amount being the amount of change in line width between before and after the slimming treatment process is held in advance in the control unit 50. Specifically, the slimming treatment process is performed, with the heat treatment condition changed, on a plurality of wafers different from wafers to be treated, and data of the slim amount being the amount of change in line width between before and after the slimming treatment process is measured, and the control unit 50 obtains and holds the data of correlation between the heat treatment condition and the slim amount.

In this embodiment, a series of slimming treatment processes including the heat treatment process with the heat treatment temperature, as an example of the heat treatment condition, changed for each of a plurality of wafers are performed on the wafers, and the slim amount of each of the wafers between before and after the slimming treatment process is measured. Assuming that the heat treatment time is fixed (for example 60 sec), the relation between the heat treatment temperature (bake temperature) and the slim amount exhibits a substantially linear relation and has a positive correlation as shown in FIG. 7. Because of the positive correlation between the heat treatment temperature (bake temperature) and the slim amount, it is possible to calculate and estimate the slim amount when the heat treatment temperature is changed when the slimming treatment process according to the slimming treatment method in this embodiment is performed afterwards. In short, it is possible to set the heat treatment temperature (bake temperature) for obtaining a desired slim amount.

For example, it is assumed that the measurement value of the line width measured in the first line width measurement process is 42 nm. For decreasing the line width to 35 nm, it is necessary to set the slim amount to 7 nm. In such a case, the heat treatment temperature (bake temperature) only needs to be set at 60° C. that is the heat treatment temperature (bake temperature) corresponding to the slim amount of 7 nm.

In the above-described manner, the heat treatment condition can be determined at Step S16 based on the data of the correlation between the heat treatment condition and the slim amount held in advance in the control unit 50 and on the measurement value of the line width measured in the first line width measurement process.

Subsequently, the reactant coating process at Step S17 is performed. The reactant coating process is a process of applying a reactant which solubilizes the resist pattern, onto the resist pattern. FIG. 6E shows the structure of the resist pattern after the process at Step S17 is performed.

At Step S17, the coating module COT in the coating and developing apparatus 2 is used, for example, to apply a solvent containing a reactant solubilizing the resist pattern 103c onto the resist pattern 103c as shown in FIG. 6E. An example of the reactant is acid. As an example of an acidic solution containing acid, for example, a top anti-reflection coating (TARC) can be used. Specifically, the reactant, for example, a solution 104a containing acid (H⁺) is applied onto the resist pattern 103c.

Subsequently, the heat treatment process at Step S18 is performed. The heat treatment process is a process of performing a heat treatment under the heat treatment condition determined in advance to diffuse the reactant into the resist pattern 103c. FIG. 6F shows the structure of the resist pattern after Step S18 is performed.

At Step S18, the heat treatment is performed at the heat treatment temperature determined in advance to diffuse the reactant into the resist pattern 103c as shown in FIG. 6F, thereby forming a new soluble layer 103e on the front surface of the resist pattern 103c. As shown in FIG. 6F, the substrate on which the resist pattern 103c is formed, for example, the semiconductor wafer W is baked using a baker 105, whereby the diffusion amount of the reactant, for example, acid (H⁺) can be increased. Alternatively, for example, the heating module PEB or the like in the coating and developing apparatus 2 may be used. Further, the bake can activate the acid (H⁺) diffused into the resist pattern 103c and promote change of the insoluble layer 103b to the new soluble layer 103e. An example of the change of the insoluble layer 103b to the new soluble layer 103e is, for example, change from an alkali-insoluble protecting group to an alkali-soluble group (solubilized substance) using acid (H+) as a catalyst.

Because the heat treatment temperature at this time is the heat treatment temperature determined based on the line width measured in the first line width measurement process, the line width can be decreased to a predetermined line width even when there are variations in line width measured in the first line width measurement process.

Note that a too high bake temperature causes pattern collapse or pattern fall, and therefore it is preferable to set the upper limit for the bake temperature. The upper limit of the bake temperature differs depending on the kind of the resist constituting the resist pattern 103c, but can be 110° C. in an example show in this embodiment. Further, the preferable bake temperature ranges from 50° C. to 180° C.

After Step 17 and Step S18 are performed to form the new soluble layer 103e by liquid-phase diffusion as described above, Step S19 is performed. Step S19 is a process of removing the new soluble layer 103e from the resist pattern 103c having the new soluble layer 103e formed thereon. An example of removal, a developing treatment can be performed. Here, an example in which the third development process is performed as step S19 will be explained. FIG. 6G shows the structure of the resist pattern after the process at Step S19 is performed.

At Step S19, the developing unit DEV in the coating and developing apparatus 2 is used, for example, to spray the alkaline solvent (developing solution) onto the resist pattern 103c on which the new soluble layer 103e has been formed, thereby removing the new soluble layer 103e as shown in FIG. 6G. After Step S19 is performed, post-bake is performed, when necessary, in order to harden the resist pattern 103c.

According to this embodiment, after the first development process shown in FIG. 6C, the removal process (the second development process) for the intermediate exposure region 103d shown in FIG. 6D and the removal process (the third development process) for the new soluble layer 103e shown in FIG. 6G are performed. By removing the intermediate exposure region 103d and the new soluble layer 103e, the resist pattern 103c can be formed which has a line width CDfnl smaller than the line width CDint of the resist pattern 103c after the first development process is performed.

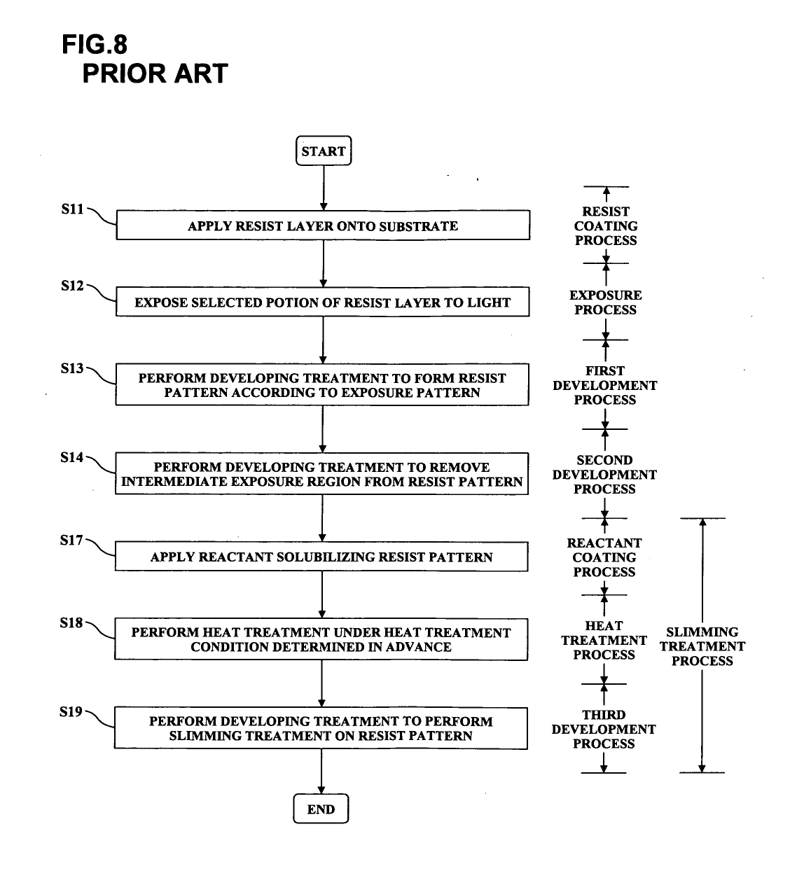

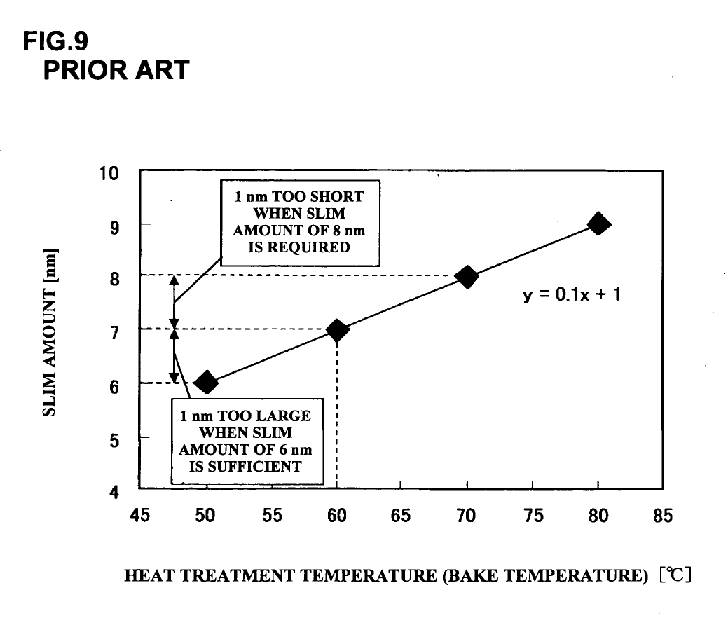

Subsequently, the resist pattern slimming treatment method according to this embodiment is compared to the conventional slimming treatment method with reference to FIG. 7, FIG. 8, and FIG. 9. Then, the operation and effect capable of reducing the variations in line width of the resist pattern after the slimming treatment, by performing the resist pattern slimming treatment method according to this embodiment will be described.

FIG. 8 is a flowchart for explaining a procedure of processes of the conventional resist pattern slimming treatment method and resist pattern forming method. FIG. 9 is a graph for explaining that the variations in line width before the slimming treatment process are not corrected in the conventional resist pattern slimming treatment method.

In the resist pattern slimming treatment method according to this embodiment, when there are variations in line width between wafers before the slimming treatment process, the heat treatment condition can be changed to correct the variations. For example, when the line width before the slimming treatment process is 42 nm, the heat treatment is performed at 60° C. that is the fixed heat treatment temperature (bake temperature) to realize the slim amount of 7 nm, resulting in a line width after the slimming treatment process of 35 nm as shown in FIG. 7.

Besides, when the line width before the slimming treatment process is 43 nm, the slim amount should be 8 nm to obtain a line width after the slimming treatment process of 35 nm. Since the heat treatment temperature (bake temperature) corresponding to the slim amount of 8 nm is 70° C. as shown in FIG. 7, the line width after the slimming treatment process can be made uniform to 35 nm by setting the heat treatment temperature (bake temperature) in the heat treatment process to 70° C.

Besides, when the line width before the slimming treatment process is 41 nm, the slim amount should be 6 nm to obtain a line width after the slimming treatment process of 35 nm. Since the heat treatment temperature (bake temperature) corresponding to the slim amount of 6 nm is 50° C. as shown in FIG. 7, the line width after the slimming treatment process can be made uniform to 35 nm by setting the heat treatment temperature (bake temperature) in the heat treatment process to 50° C.

Therefore, use of the resist pattern slimming treatment method according to this embodiment makes it possible to reduce the variations in line width of a resist pattern after the slimming treatment process.

In contrast, in the conventional resist pattern slimming treatment method, the variations in line width of a resist pattern after the slimming treatment process cannot be reduced.

In the conventional resist pattern slimming treatment method, the first line width measurement process and the heat treatment condition determination process in the resist pattern slimming treatment method according to this embodiment are not performed as shown in FIG. 8. In the case where the first line width measurement process is not performed, after completion of the second development process on each treated wafer, the line width of the resist pattern on each wafer is not measured. Therefore, whether there are variations in line width among wafers is not recognized. Besides, in the case where the heat treatment condition determination process is not performed, even if there are variations in line width among wafers, the heat treatment process is performed under a fixed heat treatment condition, for example, at a fixed heat treatment temperature on the wafers. Therefore, if there are variations in line width among wafers before the slimming treatment process, change of the heat treatment condition to correct the variations cannot be performed, and therefore the variations in line width among the wafers remain even after the slimming treatment process.

As shown in FIG. 9, when the line width before the slimming treatment process is 42 nm, the heat treatment is performed at 60° C. that is the fixed heat treatment temperature (bake temperature) to realize the slim amount of 7 nm, resulting in a line width after the slimming treatment process of 35 nm. However, when the line width before the slimming treatment process is 43 nm, the slim amount is kept at 7 nm because the heat treatment is performed at 60° C. that is the fixed heat treatment temperature (bake temperature). Then, the line width after the slimming treatment process becomes 36 nm that is larger by 1 nm than 35 nm that is the appropriate line width. Also when the line width before the slimming treatment process is 41 nm, the slim amount is kept at 7 nm because the heat treatment is performed at 60° C. that is the fixed heat treatment temperature (bake temperature). Then, the line width after the slimming treatment process becomes 34 nm that is smaller by 1 nm than the appropriate line width.

Consequently, by performing the resist pattern slimming treatment method according to this embodiment, the variations in line width of the resist pattern after the slimming treatment can be reduced as compared to the conventional slimming treatment method.

In the resist pattern slimming treatment method according to this embodiment, the line width of a resist pattern is measured before the slimming treatment process, and the measurement result is reflected in the heat treatment condition in the heat treatment process. This makes it possible to adjust the line width dimension of the resist pattern after the slimming treatment process to a desired line width dimension.

Further, the distribution of the line width within a wafer is measured in the first line width measurement process, and the temperature distribution within the wafer is controlled in the heat treatment process. Thus, even if there are variations in line width within a wafer, the method according to this embodiment can be used to correct the variations in line width within the wafer to reduce the variations in line width within the wafer.

Further, the method of changing the heat treatment temperature as the heat treatment condition to perform the correction is illustrated in this embodiment. However, the heat treatment condition is not limited to the heat treatment temperature but may be, for example, time or the like. Further, conditions in the slimming treatment process other than the heat treatment condition may be changed and, for example, any of the developing treatment temperature and the developing treatment time, and the concentration of acid to be applied as the reactant in the third development process may be changed.

Further, as has been described in this embodiment, the target value of the line width after the slimming treatment process is the desired line width in design. However, as described in a second embodiment, the target value of the line width after the slimming treatment process may be set, during a process, to a value according to the yield of the process. Alternatively, for the double patterning in which the lithography for the second time is performed to add a resist pattern in spaces in a resist pattern formed by the lithography for the first time so as to form a fine resist pattern, the line width of the resist pattern formed by the lithography for the first time may be set as the target value of the line width of the additional resist pattern to be formed by the lithography for the second time.

Further, the example in which the first line width measurement process is performed between the second development process and the reactant coating process has been illustrated in this embodiment. The first line width measurement process, however, may be performed at any time between the first development process and the heat treatment process.

Besides, in the case where the resist pattern slimming treatment method according to this embodiment is performed using the coating and developing apparatus 2, it is possible to perform the second development process in the developing unit DEV, and then perform the first line width measurement process in the inspection module IM1, and thereafter perform the reactant coating process in the coating module COT. However, a coating and developing apparatus may be used in which a unit corresponding to the inspection module is provided as an in-line module in or near a unit such as the developing unit DEV, the coating module COT, the baker 105, the heating module PEB or the like. In this case, the first line width measurement process may be performed at the same time with any of the first development process, the second development process, the reactant coating process, and the heat treatment process.

Further, the example in which the slimming treatment process composed of the reactant coating process, the heat treatment process and the third development process is performed once to thereby perform the slimming treatment has been illustrated in this embodiment. However, when a sufficient slim amount cannot be obtained by performing the slimming treatment process only once, it is also possible to perform a method of repeating the slimming treatment process a plurality of times to bring the slim amount close to the target value.

### Modification Example of First Embodiment

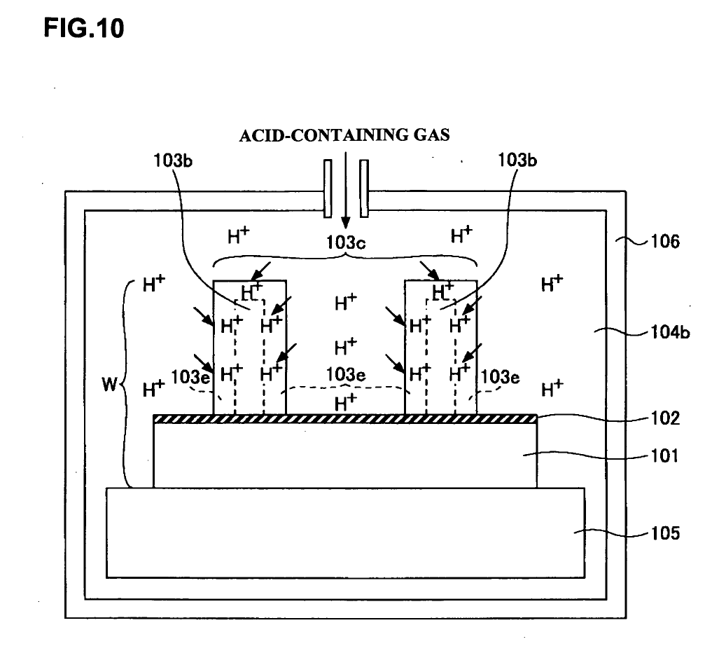

Next, a resist pattern slimming treatment method and a resist pattern forming method according to a modification example of the first embodiment will be described with reference to FIG. 10.

FIG. 10 is a sectional view schematically showing the structure on the front surface of the substrate at Step S17 and Step S18 when the resist pattern slimming treatment method according to this modification example has been performed. Further, the parts which have been previously described are given the same numerals and description thereof will be omitted in some cases (this also applies to following modification example and embodiment).

The resist pattern slimming treatment method according to this modification example is different from the resist pattern slimming treatment method according to the first embodiment in that the reactant solubilizing the resist pattern is diffused into the resist pattern by vapor-phase diffusion.

In the resist pattern slimming treatment method according to the first embodiment, the solution containing the reactant is applied onto the resist pattern 103c to diffuse the reactant into the resist pattern 103c by liquid-phase diffusion at Step S17 and Step S18. In contrast, in the resist pattern slimming treatment method according to this modification example, the resist pattern 103c is exposed to an atmosphere containing the reactant so that the reactant is diffused into the resist pattern 103c by vapor-phase diffusion.

At Step S17 and Step S18, as shown in FIG. 10, the substrate on which the resist pattern 103c is formed, for example, the semiconductor wafer W is transferred into a treatment chamber 106. Thereafter, the reactant, for example, an acid-containing gas containing acid (H⁺) is supplied into the treatment chamber 106, and the resist pattern 103c is exposed to an atmosphere 104b containing acid (H⁺). Then, the acid (H⁺) is diffused into the resist pattern 103c from the atmosphere 104b containing the acid (H⁺). In the diffusion, as shown in FIG. 10, the substrate on which the resist pattern 103c is formed, for example, the semiconductor wafer W is preferably baked using the baker 105. Through the bake, the diffusion amount of the reactant, for example, the acid (H⁺) can be increased. Further, the bake can activate the acid (H⁺) diffused in the resist pattern 103c to promote change from the insoluble layer 103b to the new soluble layer 103e. An example of the change from the insoluble layer 103b to the new soluble layer 103e is the change from the alkali-insoluble protecting group to the alkali-soluble group (solubilized substance) using the acid (H⁺) as a catalytic component also in this modification example.

Also according to this modification example, the distribution of line width within a wafer is measured in the first line width measurement process, and the temperature distribution within the wafer is controlled in the heat treatment process. Thus, even if there are variations in line width within a wafer, the variations in line width within the wafer can be corrected and the variations in line width within the wafer can be reduced.

### Second Embodiment

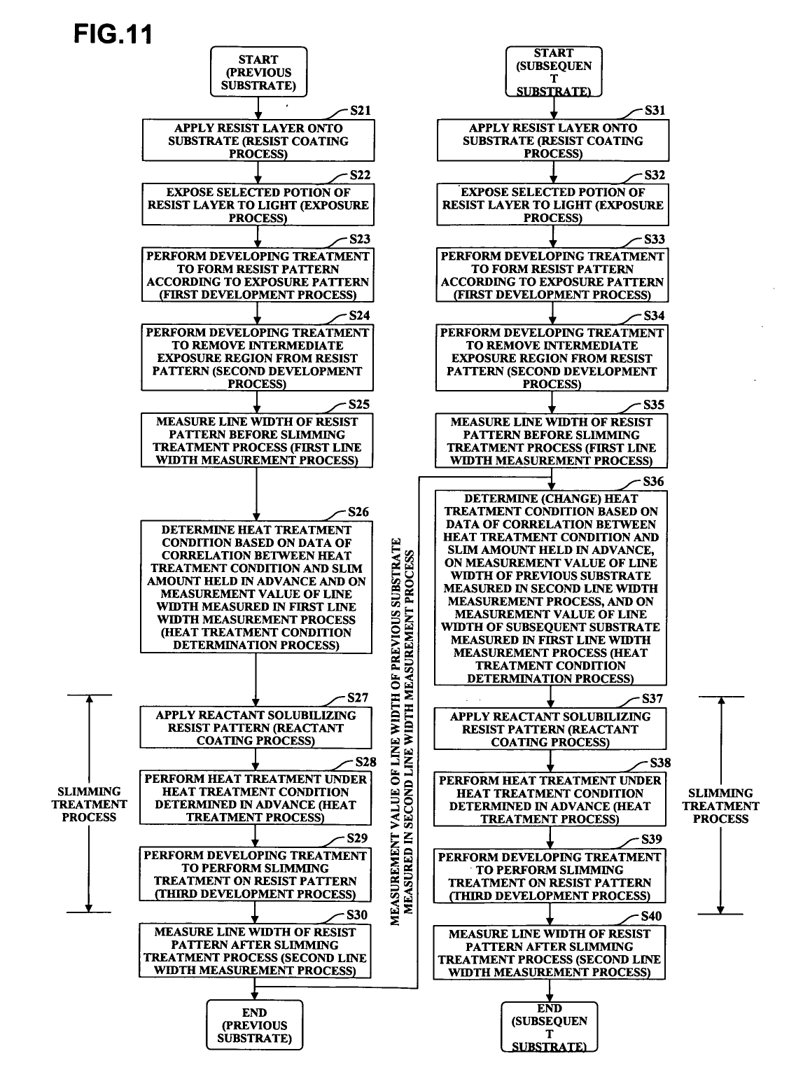

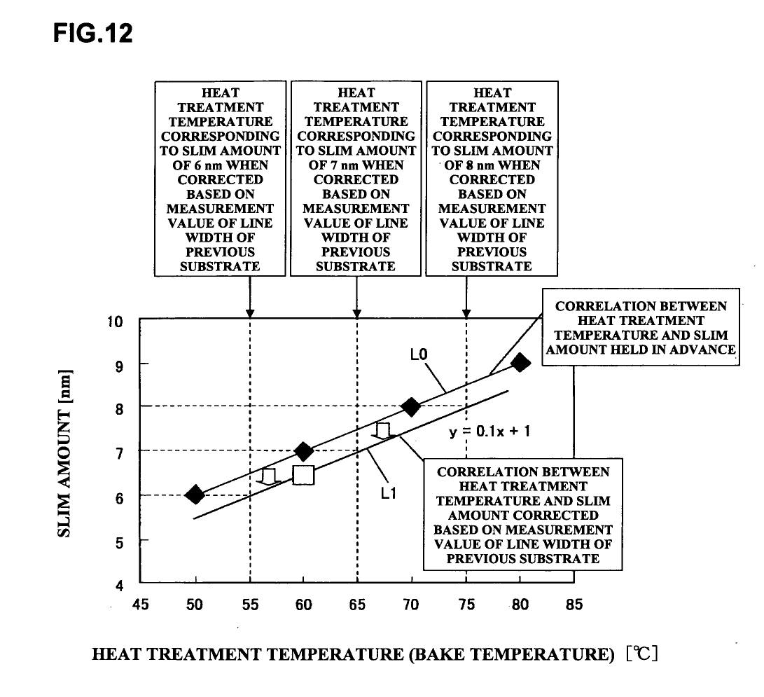

Next, a resist pattern slimming treatment method and a resist pattern forming method according to a second embodiment of the present invention will be described with reference to FIG. 11 and FIG. 12.

FIG. 11 is a flowchart for explaining a procedure of processes of the resist pattern slimming treatment method and the resist pattern forming method according to this embodiment. FIG. 12 is a graph showing the operation and effect capable of correcting variations in line width before the slimming treatment process to reduce the variations in line width after the slimming treatment process in the resist pattern slimming treatment method according to this embodiment.

The slimming treatment method according to this embodiment is different from the slimming treatment method according to the first embodiment in that a second line width measurement process is performed after the third development process.

In the resist pattern slimming treatment method according to the first embodiment, the heat treatment condition is determined based on the data of the correlation between the heat treatment condition and the slim amount held in advance and on the measurement value of the line width measured in the first line width measurement process. In contrast, in the resist pattern slimming treatment method according to this embodiment, when performing the slimming treatment process on a resist pattern of a next substrate, the heat treatment condition for the resist pattern of the next substrate is determined (or changed) based also on the measurement value of the line width of a previous substrate measured in the second line width measurement process.

Note that the coating and developing apparatus according to this embodiment is the same as the coating and developing apparatus according to the first embodiment which has been described using FIG. 1 to FIG. 4, and description thereof will be omitted here.

The resist pattern forming method including the resist pattern slimming treatment method according to this embodiment includes, as shown in FIG. 11, a resist coating process (Step S21, Step S31), an exposure process (Step S22, Step S32), a first development process (Step S23, Step S33), a second development process (Step S24, Step S34), a first line width measurement process (Step S25, Step S35), a heat treatment condition determination process (Step S26, Step S36), a slimming treatment process (Step S27 to Step S29, Step S37 to Step S39), and a second line width measurement process (Step S30, Step S40) for each of the previous substrate and the subsequent substrate. Further, the slimming treatment process includes a reactant coating process (Step S27, Step S37), a heat treatment process (Step S28, Step S38), and a third development process (Step S29, Step S39).

For the previous substrate, the processes from Step S21 to Step S29 are the same processes from Step S11 to Step S19 shown in FIG. 5 in the first embodiment, respectively.

However, for the previous substrate, the second line width measurement process being Step S30 is different from the first embodiment. The second line width measurement process is a process of measuring the line width of the resist pattern formed by performing the resist coating process at Step S21 to the third development process at Step S29 for the previous substrate. The wafer is transferred, for example, to the inspection module IM1 being the film thickness and line width inspection module using the ODP including scatterometry, and the line width thereof is measured.

Meanwhile, for the subsequent substrate, the processes from Step S31 to Step S35 are the same as the processes from Step S11 to Step S15 shown in FIG. 5 in the first embodiment, respectively.

However, for the subsequent substrate, the heat treatment condition determination process being Step S36 is different from the process at Step S16 shown in FIG. 5 in the first embodiment. In the first embodiment, the heat treatment condition determination process is a process of determining the heat treatment condition based on the data of the correlation between the heat treatment condition and the slim amount held in advance and on the measurement value of the line width measured in the first line width measurement process. On the other hand, the heat treatment condition determination process in this embodiment is a process of determining (or changing) the heat treatment condition based on the data of the correlation between the heat treatment condition and the slim amount held in advance, on the measurement value of the line width of the previous substrate measured in the second line width measurement process, and on the measurement value of the line width of the subsequent substrate measured in the first line width measurement process.

Further, for the subsequent substrate, the processes from Step S37 to Step S39 performed after Step S36 are the same as the processes at Step S17 to Step S19 shown in FIG. 5 in the first embodiment, respectively. Furthermore, the process at Step S40 performed after Step S39 is the same process as the process at Step S30 performed for the previous substrate.

In the heat treatment condition determination process being Step S36, a series of slimming treatment processes including the heat treatment process with the heat treatment temperature, as an example of the heat treatment condition, changed for each of a plurality of wafers are performed on the wafers, and the slim amount of each of the wafers between before and after the slimming treatment process is measured in advance. This process is the same as that in the first embodiment. The data held in advance indicates substantially the linear relation and has the positive correlation as shown by a line L0 in FIG. 12. In this case, it is possible to set the heat treatment temperature (bake temperature) for obtaining a desired slim amount.

However, over time after the data held in advance is obtained, there may occur inconsistency between the heat treatment temperature (bake temperature) and the slim amount, for example, due to a change in ambient temperature by heat conduction from the baker to the surroundings or the like. In such a case, the relation between the heat treatment temperature (bake temperature) and the slim amount can be updated according to the latest state by correcting the deviation of the line width of the previous substrate after the slimming treatment process from the target value.

For example, it is assumed that though the slim amount was 7 nm at the heat treatment temperature (bake temperature) of 60° C. during the time when the slimming treatment was performed for a first plurality of wafers after obtaining the data held in advance, the inconsistency gradually occurred between the heat treatment temperature (bake temperature) and the slim amount, and the slim amount was changed to 6.5 nm at the heat treatment temperature (bake temperature) of 60° C. for a preceding substrate (a previous substrate). In this case, the correlation indicated by the straight line L0 in FIG. 12 and based on the data held in advance is brought to the correlation indicated by a straight line L1 in FIG. 12 obtained by being shifted so that the slim amount is 6.5 nm at the heat treatment temperature (bake temperature) of 60° C., whereby the correlation between the heat treatment temperature and the slim amount is updated.

For example, it is assumed that the measurement value of the line width of the subsequent substrate measured in the first line width measurement process is 42 nm. For decreasing the line width to 35 nm, it is necessary to set the slim amount to 7 nm. In such a case, the heat treatment temperature (bake temperature) only needs to be set at 65° C. that is the heat treatment temperature (bake temperature) to which the slim amount of 7 nm corresponds, based on the straight line L1 indicating the newly updated correlation in the graph in FIG. 12.

Further, when the line width of the subsequent substrate before the slimming treatment process is 43 nm, the slim amount should be 8 nm in order to obtain a line width after the slimming treatment process of 35 nm. By setting the heat treatment temperature (bake temperature) to 75° C. that is the heat treatment temperature (bake temperature) to which the slim amount of 8 nm corresponds, based on the straight line L1 indicating the newly updated correlation in the graph in FIG. 12, the line width after the slimming treatment process can be made uniform to 35 nm.

Further, when the line width of the subsequent substrate before the slimming treatment process is 41 nm, the slim amount should be 6 nm in order to obtain a line width after the slimming treatment process of 35 nm. By setting the heat treatment temperature (bake temperature) to 55° C. that is the heat treatment temperature (bake temperature) to which the slim amount of 6 nm corresponds, based on the straight line L1 indicating the newly updated correlation in the graph in FIG. 12, the line width after the slimming treatment process can be made uniform to 35 nm.

Consequently, in the resist pattern slimming treatment method according to this embodiment, the line width of a resist pattern is measured before the slimming treatment process, so that the measurement result can be reflected in the heat treatment condition of the heat treatment process, and the correlation between the heat treatment condition held in advance and the slim amount can be updated to the latest state with reference to the data of the preceding substrate. This makes it possible to adjust with higher accuracy the line width dimension of the resist pattern to a desired line width dimension.

Note that when update of the data held in advance is performed when the slimming treatment is performed on a substrate, the data may be updated based only on the line width of one preceding substrate measured in the second line width measurement process as has been described in this embodiment. Alternatively, the data may be updated based on measured line widths of a plurality of substrates preceding to the substrate. Alternatively, various kinds of weighting such as adjustment to more strongly reflect the measured line width of a preceding substrate can be performed.

Further, the heat treatment condition is not limited to the heat treatment temperature but may be, for example, time or the like also in this embodiment. Furthermore, conditions in the slimming treatment process other than the heat treatment condition may be changed and, for example, the concentration of acid to be applied as the reactant may be changed.

Further, the target value of the line width after the slimming treatment process may be set, during a process, to a value according to the yield of the process also in this embodiment. Alternatively, for the double patterning in which the lithography for the second time is performed to add a resist pattern in spaces in a resist pattern formed by the lithography for the first time so as to form a fine resist pattern, the line width of the resist pattern formed by the lithography for the first time may be set as the target value for the line width of the additional resist pattern to be formed by the lithography for the second time.

Further, the first line width measurement process may be performed at any time between the first development process and the heat treatment process also in this embodiment.

Also in the case where the resist pattern slimming treatment method according to this embodiment is performed using the coating and developing apparatus 2, a coating and developing apparatus may be used in which a unit corresponding to the inspection module is provided as an in-line module in or near a unit such as the developing unit DEV, the coating module COT, the baker 105, the heating module PEB or the like. In this case, the first line width measurement process may be performed at the same time with any of the first development process, the second development process, the reactant coating process, and the heat treatment process. Furthermore, the second line width measurement process may be performed at the same time with the third development process.

Further, it is also possible to perform a method of repeating the slimming treatment process a plurality of times to bring the slim amount close to the target value, also in this embodiment.

Preferred embodiments of the present invention have been described above. However, the present invention is not limited to the particular embodiments but can be variously changed and modified within the scope of the invention as set forth in claims.

What is claimed is:

1. A resist pattern slimming treatment method of performing a slimming treatment on a resist pattern formed on a substrate, comprising:
a slimming treatment step of performing a slimming treatment on the resist pattern by applying a reactant solubilizing the resist pattern onto the resist pattern, then performing a heat treatment on the resist pattern under a heat treatment condition determined in advance, and then performing a developing treatment on the resist pattern; and
a first line width measurement step of measuring a line width of the resist pattern before said slimming treatment step,
wherein the heat treatment condition is determined based on a measurement value of the line width measured in said first line width measurement step.

2. The resist pattern slimming treatment method as set forth in claim 1, further comprising:
a second line width measurement step of measuring the line width of the resist pattern after said slimming treatment step,
wherein after said slimming treatment step is performed on the resist pattern on the substrate, when said slimming treatment step is performed on a resist pattern on a next substrate, the heat treatment condition of said slimming treatment step performed on the resist pattern on the next substrate is changed based on a measurement value of the resist pattern on the substrate measured in said second line width measurement step.

3. The resist pattern slimming treatment method as set forth in claim 2,
wherein the heat treatment condition is temperature.

4. The resist pattern slimming treatment method as set forth in claim 3,
wherein said first line width measurement step is performed by a unit provided in an apparatus performing said slimming treatment step.

5. The resist pattern slimming treatment method as set forth in claim 2,
wherein said first line width measurement step is performed by a unit provided in an apparatus performing said slimming treatment step.

6. The resist pattern slimming treatment method as set forth in claim 2,
wherein said second line width measurement step is performed by a unit provided in an apparatus performing said slimming treatment step.

7. The resist pattern slimming treatment method as set forth in claim 1,
wherein the heat treatment condition is temperature.

8. The resist pattern slimming treatment method as set forth in claim 7,
wherein said first line width measurement step is performed by a unit provided in an apparatus performing said slimming treatment step.

9. The resist pattern slimming treatment method as set forth in claim 1,
wherein said first line width measurement step is performed by a unit provided in an apparatus performing said slimming treatment step.
